(19) United States
(12) Patent Application Publication
(10) Pub. No.: US 2006/0156132 A1
(43) Pub. Date: Jul. 13, 2006

(54) Semiconductor device with built-in scan test circuit

(75) Inventors: Satoru Koishikawa, Ora-gun (JP); Tadashi Watanabe, Ota-shi (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/274,482

(22) Filed: Nov. 16, 2005

(30) Foreign Application Priority Data
Nov. 18, 2004 (JP) 2004-333913

(51) Int. Cl. G01R 31/28

(52) U.S. Cl. 714/733

(57) ABSTRACT

The clock cycle during the shift operation is set shorter than the clock cycle during the capture operation in the scan test circuit. For example, the clock cycle during the shift operation is set to 20 nano second, while the clock cycle during the capture operation is set to 100 nano second. The clock is fed from a LSI tester outside of the LSI through the clock terminal CLK. The cycle of the clock can be switched to synchronize with the change of the scan enable signal SCANEN by the LSI tester. The time for shift operation can be shortened in this invention, leading to the shorter scan test time.

### CROSS-REFERENCE OF THE INVENTION

This invention is based on Japanese Patent Application No. 2004-333913, the content of which is incorporated herein by reference in its entirety.

### BACKGROUND OF THE INVENTION

1. Field of Invention

This invention relates to a scan test circuit for simplifying the test of a large scale integrated circuit.

2. Description of Related Art

Testing by a LSI tester is usually performed when a large scale integrated circuit (referred to as LSI hereinafter) is shipped to the market. The objective of the test pattern for this testing is to find defects in a plurality of the logic circuits that configures a LSI as much as possible.

However, as the scale of LSI gets larger, the larger test vector and longer testing time are required to perform the test on the entire logic circuits. The circuit design for testability has been sought for solving this problem.

The design for testability is the designing method where the test strategy is determined while a LSI is designed, and where the test circuit has been built-in in the LSI. The basic criteria for easy testing include the observability and controllability. When a circuit has a good observability, it is easy to observe the logical value of a node in the circuit. And, it is easy to determine a logical value of a node in the circuit through the data inputted from outside when a circuit has a good controllability. The better observability and controllability of a circuit leads to the more efficient test pattern, and as a result, leads to the improved defect detection of the logic circuits. One of the test circuits with the improved observability and controllability is a scan test circuit.

A scan test circuit is the circuit which has a flip flop circuit corresponding to each of the logic circuits in a LSI. A plurality of flip flop circuits are connected in a chain form, configuring a shift resistor that performs shift operation for consecutively shifting the data coming into the flip flop circuit and capture operation for capturing the output of each of the logic circuits into each of the flip flop circuits.

That is, the data of each of the flip flop circuits is sent as a test signal to each of the logic circuit through the first shift operation, and the output data of each of the logic circuits is captured by each of the flip flop circuits through the next capture operation. Then, the output data from each of the logic circuits captured by each of the flip flop circuits is chronologically acquired from the last row of the flip flop circuit through the next shift operation. The testing is performed by comparing the output data of each of the logic circuits acquired in the manner described above with the expected values. Japanese Patent Application No. 2001-59856 is the technical document that relates to this invention.

However, the scan test circuit that repeats the shift operation and the capture operation takes longer testing time and requires higher testing cost. Especially, the shift operation should be repeated as many times as the number of the flip flops that configures the shift resistor, taking most of the test time.

### SUMMARY OF THE INVENTION

The invention provides a semiconductor device with a built-in scan test circuit having a plurality of logic circuits and a scan flip flop circuit provided for each of the logic circuits and receiving a scan signal. The scan flip flop circuit includes a shift resistor that performs a shift operation according to a first clock when the scan enable signal is at a first level and performs a capture operation to capture an output data of a corresponding logic circuit according to a second clock when the scan enable signal is at a second level, and the first clock is shorter than the second clock.

### BRIEF DESCRIPTION OF THE DRAWINGS

FIG. 1 is a circuit diagram showing an embodiment of the scan test circuit of this invention.

FIG. 2 is the diagram showing the operation mode of an embodiment of the scan test circuit of this invention.

FIG. 3 is a clock waveform diagram of the scan test circuit of prior arts.

FIG. 4 is a clock waveform diagram of an embodiment of the scan test circuit of this invention.

### DETAILED DESCRIPTION OF THE INVENTION

The scan test circuit of this invention will be explained by referring to the drawings.

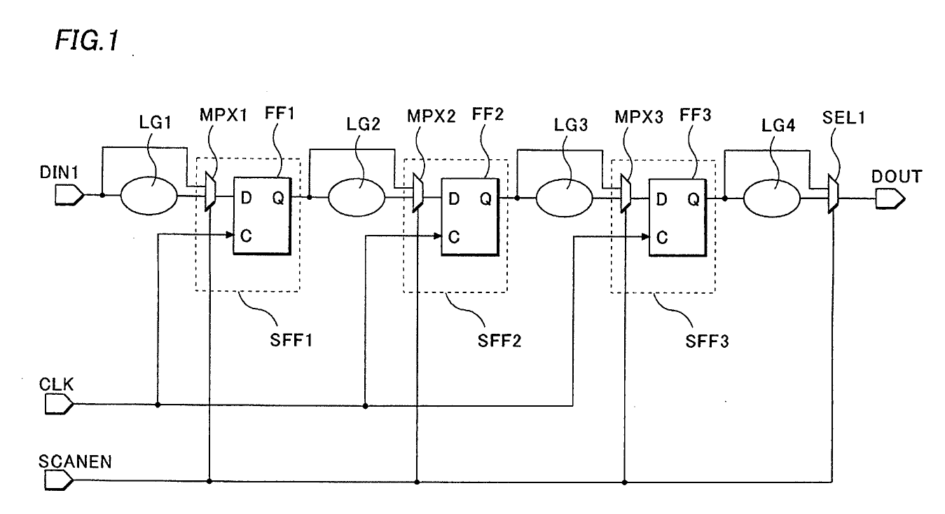

FIG. 1 is a circuit diagram showing the scan test circuit of an embodiment of this invention. First, second and third scan flip flop circuits, SFF1, SFF2, and SFF3 are disposed between first, second, third, and fourth logic circuits, LG1, LG2, LG3, LG4 respectively. The first, second third and fourth logic circuits LG1, LG2, LG3, LG4 are based on a combination of logic circuits including AND circuit and NAND circuit.

The first scan flip flop circuit SFF1 has a first multiplexer MPX1 and a D type flip flop circuit FF1 (delayed flip flop circuit). The first multiplexer MPX1 selects a scan test signal from a data input terminal DIN or an output of the first logic circuit LG1 corresponding to the scan test signal according to a scan enable signal SCANEN, and then outputs the selected signal to the input terminal D of the first D type flip flop circuit FF1.

The second scan flip flop circuit SFF2 has a second multiplexer MPX2 and a second D type flip flop circuit FF2. The second multiplexer MPX2 selects the scan test signal from the first scan flip flop circuit SFF1 at the previous row or an output of the second logic circuit LG2 corresponding to the scan test signal according to the scan enable signal SCANEN, and then outputs the selected signal to the input terminal D of the second D type flip flop circuit FF2.

The third scan flip flop circuit SFF3 has a third multiplexer MPX3 and a third D type flip flop circuit FF3. The third multiplexer MPX3 selects the scan test signal from the second scan flip flop circuit SFF2 at the previous row or an output of the third logic circuit LG3 corresponding to the scan test signal according to the scan enable signal SCANEN, and then outputs the selected signal to the input terminal D of the third D type flip flop circuit FF3.

Clock input terminals C of the first, second and third D type flip flop circuits FF1, FF2, FF3 receive the common clock signal from a clock terminal CLK. Although only three logic circuits and three scan flip flop circuits are shown in the FIG. 1, the number of the logic circuits and its corresponding scan flip flop circuits ranges from several thousands to several ten thousands in an actual LSI.

A selector SEL1 selects the scan test signal from the third scan flip flop circuit SFF3 at the previous row or an output of the third logic circuit LG3 corresponding to the scan test signal according to a scan enable signal SCANEN, and then outputs the selected signal to a data output terminal Dout.

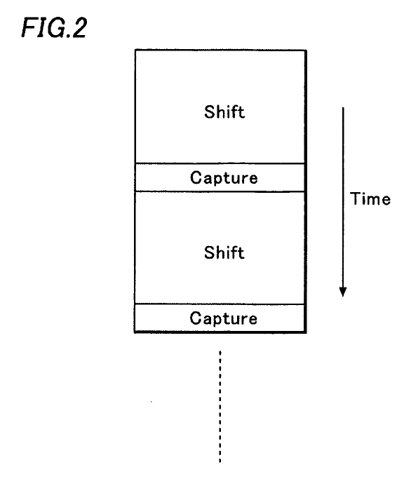

Next, operation of the scan test circuit described above will be explained by referring to FIG. 2. The scan test circuit is set as a shift mode when the scan enable signal SCANEN is at high level. That is, the first multiplexer MPX1 selects the scan test signal from the input terminal DIN1, the second multiplexer MPX2 selects the scan test signal from the first scan flip flop circuit SFF1, the third multiplexer 3 MPX3 selects the scan test signal from the second scan flip flop circuit SFF2, and the selector SEL1 selects the scan test signal from the third scan flip flop circuit SFF3.

The first, second, and third D type flip flop circuits FF1, FF2, FF3 are connected in a chain form, configuring a shift resistor. Therefore, the scan test signal from the data input terminal DIN1 is consecutively fed from the output terminal Q of the D type flip flop circuit to the input terminal of the next D type flip flop circuit at each clock inputted from the clock input terminal. That is, a shift operation is performed for the time corresponding to the three-clock time.

Next, the scan test circuit is set as a capture mode when the scan enable signal SCANEN changes to low level. That is, the first multiplexer MPX1 selects the output data from the first logic circuit LG1, the second multiplexer MPX2 selects the output data from the second logic circuit LG2, the third multiplexer MPX3 selects the output data from the third logic circuit LG3, and the selector SEL1 selects the output data from the fourth logic circuit LG4.

The output data from the first, second and third logic circuits LG1, LG2, LG3 are captured by and kept at the first, second and third D type flip flop circuit FF1, FF2, and FF3 respectively. The first, second and third D type flip flop circuits FF1, FF2, FF3 receive each of the output data simultaneously. Therefore, all the operation for keeping the entire data is done for the time equivalent to one-clock time.

Then, the scan test circuit is set back as shift mode when the scan enable signal SCANEN changes to high level. The first, second, and third D type flip flop circuits FF1, FF2, FF3 are connected in a chain form, configuring a shift resistor again. Therefore, the output data from the first, second and third logic circuits LG1, LG2, LG3 that are kept at the first, second and third D type flip flop circuits FF1, FF2, and FF3 are shifted for each clock inputted from the clock input terminal CLK and each output data can be observed chronologically at the data output terminal Dout. Then, the testing is performed by comparing the output data of each of the logic circuits acquired in the manner described above to the expected value.

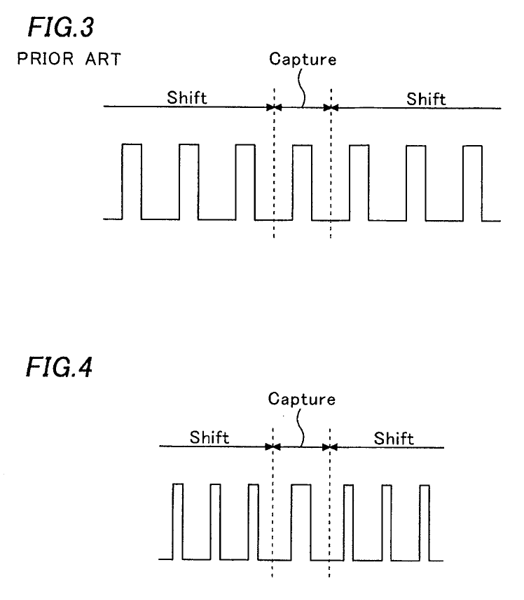

In this embodiment, the clock cycle is shortened during the shift operation compared to the clock cycle during the capture operation. In comparison, the clock cycle during the shift operation is the same as that during the capture operation in the conventional scan test circuits, as shown in FIG. 3. The clock cycle is determined to assure the time enough for the capture operation, for example, 100 nano second.

However, the cycle of the clock during the shift operation is shorter than the cycle of the clock during the capture operation in this embodiment, in recognition that it is possible to operate the shift resistor faster during the shift operation than during the capture operation, as shown in FIG. 4. For example, the cycle of the clock is set to 20 nano second for the shift operation, while the cycle of the clock is set to 100 nano second for the capture operation.

The clock is fed from a LSI tester outside of the LSI through the clock terminal CLK. The cycle of the clock can be switched to synchronize with the change of the scan enable signal SCANEN by the LSI tester. The time for shift operation can be shortened in this manner in this invention, leading to the shorter scan test time.

What is claimed is:

1. A semiconductor device with a built-in scan test circuit, comprising:
a plurality of logic circuits; and
a scan flip flop circuit provided for each of the logic circuits and receiving a scan signal;
wherein the scan flip flop circuit comprises a shift resistor that performs a shift operation according to a first clock when the scan enable signal is at a first level and performs a capture operation to capture an output data of a corresponding logic circuit according to a second clock when the scan enable signal is at a second level, and the first clock is shorter than the second clock.

2. The semiconductor device of claim 1, wherein the capture operation is performed for a period of one clock.

3. The semiconductor device of claim 1, wherein the scan flip flop circuit further comprises a multiplexer selecting the output of the corresponding logic circuit when the scan enable signal is at the second level and selecting the output of a scan flip flop circuit positioned prior to the scan flip flop circuit in a shift operation sequence when the scan enable signal is at the first level.
